(19) United States
(12) Patent Application Publication
(10) Pub. No.: US 2025/0296128 A1
(43) Pub. Date: Sep. 25, 2025

(54) METHOD AND APPARATUS FOR PARTICLE REMOVAL

(71) Applicant: ASML NETHERLANDS B.V., Veldhoven (NL)

(72) Inventors: Wei GUO, Wilton, CT (US); Justin Lloyd KREUZER, Trumbull, CT (US); Stephen ROUX, New Fairfield, CT (US)

(73) Assignee: ASML NETHERLANDS B.V., Veldhoven (NL)

(21) Appl. No.: 18/863,634

(22) PCT Filed: Jun. 30, 2023
(86) PCT No.: PCT/EP2023/067965

§ 371 Date: Nov. 6, 2024

Related U.S. Application Data
(60) Provisional application No. 63/392,671, filed on Jul. 27, 2022.

(51) Int. Cl. B08B 7/02; G03F 1/82

(52) U.S. Cl. CPC B08B 7/028; G03F 1/82

(57) ABSTRACT

A system for removing particles from a surface includes a plurality of ultrasonic transducers, arranged in an array, a control system, in communication with the plurality of ultrasonic transducers, the control system configured to control phase and amplitude of transducers in the array to generate an acoustic particle trap at a selected location on the surface, and to move a particle trapped in the particle trap away from the surface, and an actuator, configured and arranged to relatively move the array of ultrasonic transducers in a scanning pattern over the surface such that different portions of the surface pass through the generated acoustic particle trap.

### CROSS-REFERENCE TO RELATED APPLICATIONS

This application claims priority of U.S. application 63/392,671 which was filed on Jul. 27, 2022 and which is incorporated herein in its entirety by reference.

### FIELD

The description herein relates generally to systems and methods for non-contact removal of particular contamination. More particularly, it relates to the use of ultrasonic fields to effect such removal.

### BACKGROUND

A lithography apparatus can be used, for example, in the manufacture of integrated circuits (ICs). In such a case, a patterning device (e.g., a mask) may contain or provide a device pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern of the patterning device. In general, a single substrate contains a plurality of adjacent target portions to which the pattern is transferred successively by the lithography apparatus, one target portion at a time. In one type of lithography apparatuses, the pattern of the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern of the patterning device are transferred to one target portion progressively. Since, in general, the lithography apparatus will have a magnification factor M (generally <1), the speed F at which the substrate is moved will be a factor M times that at which the projection beam scans the patterning device.

Prior to transferring the pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern of the patterning device to a substrate and typically, but optionally, involves one or more related pattern processing steps, such as resist development by a development apparatus, baking of the substrate using a bake tool, etching using the pattern using an etch apparatus, etc.

### SUMMARY

In an embodiment, a system for removing particles from a surface includes a plurality of ultrasonic transducers, arranged in an array, a control system, in communication with the plurality of ultrasonic transducers, the control system configured to control phase and amplitude of transducers in the array to generate an acoustic particle trap at a selected location on the surface, and to move a particle trapped in the acoustic particle trap away from the surface, and an actuator configured to move the array of ultrasonic transducers in a scanning pattern over the surface such that different portions of the surface pass through the acoustic particle trap.

In an embodiment, a method of removing particles from a surface includes passing an array of ultrasonic transducers over the surface, during the passing, controlling a phase and amplitude of ultrasonic signals produced by ultrasonic transducers in the array such that an acoustic particle trap is generated at a location on the surface, and trapping at least one particle in the acoustic particle trap, and controlling a phase an amplitude of ultrasonic signals produced by the ultrasonic transducers in the array to move the trapped at least one particle away from the surface.

In an embodiment, there is provided a computing system including a processor and a memory, and including a non-transitory machine readable medium including instructions for performing the foregoing method.

In an embodiment, there is provided a computer program product including a computer non-transitory readable medium having instructions recorded thereon, the instructions when executed by a computer implementing the foregoing method.

### BRIEF DESCRIPTION OF THE DRAWINGS

FIG. 1 illustrates a schematic diagram of a lithography apparatus;

FIG. 2 depicts an embodiment of a lithographic cell or cluster;

FIG. 3 is a schematic illustration of a non-contact particle cleaning device in accordance with an embodiment; and

FIG. 4 is a schematic illustration of a hemispherical array made up of blocks of transducers.

### DETAILED DESCRIPTION OF THE DRAWINGS

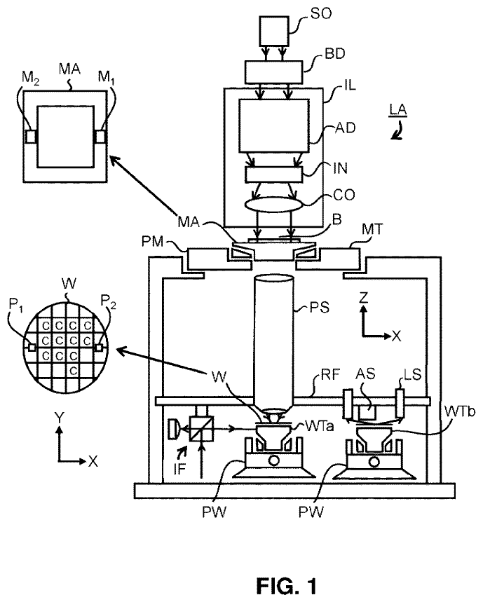

FIG. 1 schematically depicts a lithographic apparatus LA in association with which the techniques described herein can be utilized. The apparatus includes an illumination optical system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; one or more substrate tables (e.g., a wafer table) WTa, WTb constructed to hold a substrate (e.g., a resist coated wafer) W and connected to a second positioner PW configured to accurately position the substrate in accordance with certain parameters; and a projection optical system (e.g., a a refractive, catoptric or catadioptric optical system) PS configured to project a pattern imparted to the radiation beam B by patterning device MA onto a target portion C (e.g., including one or more dies) of the substrate W.

The illumination optical system may include various types of optical components, such as refractive, reflective, magnetic, electromagnetic, electrostatic or other types of optical components, or any combination thereof, for directing, shaping, or controlling radiation. In this particular case, the illumination system also comprises a radiation source SO.

The patterning device support holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support may be a frame or a table, for example, which may be fixed or movable as required. The patterning device support may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

As here depicted, the apparatus is of a transmissive type (e.g., employing a transmissive patterning device). However, the apparatus may be of a reflective type (e.g., employing a programmable mirror array of a type as referred to above, or employing a reflective mask). The apparatus may employ a different kind of patterning device to classic mask; examples include a programmable mirror array or LCD matrix.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO (e.g., a mercury lamp or excimer laser, LPP (laser produced plasma) EUV source). The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD for adjusting the spatial and/or angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the patterning device support (e.g., mask table) MT, and is patterned by the patterning device. Having traversed the patterning device (e.g., mask) MA, the radiation beam B passes through the projection optical system PS, which focuses the beam onto a target portion C of the substrate W, thereby projecting an image of the pattern on the target portion C. With the aid of the second positioner PW and position sensor IF (e.g., an interferometric device, linear encoder, 2-D encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using patterning device alignment marks M₁, M₂ and substrate alignment marks P₁, P₂. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the patterning device alignment marks may be located between the dies. Small alignment markers may also be included within dies, in amongst the device features, in which case it is desirable that the markers be as small as possible and not require any different imaging or process conditions than adjacent features. The alignment system, which detects the alignment markers, is described further below.

Lithographic apparatus LA in this example is of a so-called dual stage type which has two substrate tables WTa, WTb and two stations—an exposure station and a measurement station—between which the substrate tables can be exchanged. While one substrate on one substrate table is being exposed at the exposure station, another substrate can be loaded onto the other substrate table at the measurement station and various preparatory steps carried out. The preparatory steps may include mapping the surface control of the substrate using a level sensor LS, measuring the position of alignment markers on the substrate using an alignment sensor AS, performing any other type of metrology or inspection, etc. This enables a substantial increase in the throughput of the apparatus. More generally, the lithography apparatus may be of a type having two or more tables (e.g., two or more substrate tables, a substrate table and a measurement table, two or more patterning device tables, etc.). In such “multiple stage” devices a plurality of the multiple tables may be used in parallel, or preparatory steps may be carried out on one or more tables while one or more other tables are being used for exposures. Twin stage lithography apparatuses are described, for example, in U.S. Pat. No. 5,969,441, incorporated herein by reference in its entirety.

While a level sensor LS and an alignment sensor AS are shown adjacent substrate table WTb, it will be appreciated that, additionally or alternatively, a level sensor LS and an alignment sensor AS can be provided adjacent the projection system PS to measure in relation to substrate table WTa.

The depicted apparatus can be used in a variety of modes, including for example a step mode or a scan mode. The construction and operation of lithographic apparatus is well known to those skilled in the art and need not be described further for an understanding of the embodiments of the present invention.

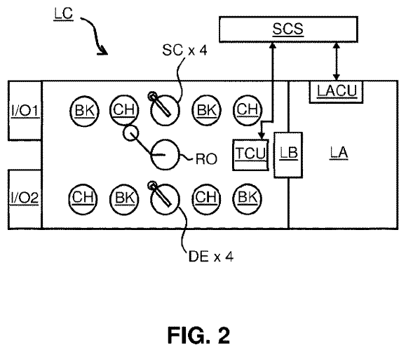

As shown in FIG. 2, the lithographic apparatus LA forms part of a lithographic system, referred to as a lithographic cell LC or a lithocell or cluster. The lithographic cell LC may also include apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

The patterning device referred to above comprises, or can form, one or more design layouts or patterns (hereinafter design pattern for convenience). The design pattern can be generated utilizing CAD (computer-aided design) programs, this process often being referred to as EDA (electronic design automation). Most CAD programs follow a set of predetermined design rules in order to create functional design patterns/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. One or more of the design rule limitations may be referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The illumination system provides illumination (i.e., radiation) in the form of an illumination mode to a patterning device and the projection system directs and shapes the illumination, via the patterning device, onto a substrate via aerial image (AI). The illumination mode defines the characteristics of the illumination, such as the angular or spatial intensity distribution (e.g., conventional, dipole, annular, quadrupole, etc.), an illumination sigma (σ) setting, etc. The aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer.

A set of conditions for imaging can be considered, and of the total set of possible conditions, a process window of a pattern is a space in that set of conditions in which processing parameters for producing the pattern are such that satisfactory imaging of the pattern is achieved. That is, for a given pattern, there may be a set of values of depth of focus, illumination intensity, illumination pattern, numerical aperture, and other controllable variables produce images having sufficiently good imaging of lines or features including linewidth, pitch, or other aspects of the imaged pattern that are defined as meeting the specifications for the required imaging. The process window gives an indication of the process sensitivity to variations in input parameters such as radiation dose.

Processing parameters are parameters of the patterning process. The patterning process may include processes upstream and downstream to the actual lithographic transfer of the pattern. Processing parameters may belong to a number of categories. A first category may be parameters of the lithography apparatus or any other apparatuses used in the patterning process. Examples of this category include parameters of the illumination system, projection system, substrate stage, etc. of a lithography apparatus. A second category may be parameters of any procedures performed in the patterning process. Examples of this category include focus, dose, bandwidth, exposure duration, development temperature, chemical compositions used in development, etc. A third category may be parameters of the design pattern. Examples of this category may include resolution enhancement technique (RET) or optical proximity correction adjustments such as shapes and/or locations of assist features. A fourth category may be parameters of the substrate. Examples include characteristics of structures under a resist layer, chemical composition of the resist layer, and/or physical dimensions of the resist layer. A fifth category may be parameters that represent a characteristic of temporal variation of one or more parameters of the patterning process. Examples of this category may include a characteristic of high frequency stage movements (e.g., frequency, amplitude, etc.), a high frequency laser bandwidth change (e.g., frequency, amplitude, etc.) and/or a high frequency laser wavelength change. These high frequency changes or movements are those above the response time of a mechanism to adjust the underlying parameter (e.g., stage position, laser intensity, etc.). A sixth category may be a characteristic upstream or downstream to exposure, such as post-exposure bake (PEB), development, etching, deposition, resist application, doping and/or packaging.

In view of the high degree of necessary accuracy, even small amounts of contamination can cause imaging problems. In one example, a particle on the backside of a reticle for use in an EUV system can cause the reticle to flex relative to the electromagnetic chuck by which it is supported. This flexing can result in overlay errors because of the change in reticle shape.

Current methods of inspection and particle removal are generally slow. A full inspection for a reticle can take 15 minutes or more. Once defects are identified, then confocal microscopy is used to measure particle size (e.g., height) at a cost of about 30 s per defect. Large particles (1-25 μm, for example) can be removed though the use of grinding methods, adhesive rod methods, or the like. Typically these methods are also performed off-line and not in-scanner. Such methods find applications in inspection and cleaning of reticles, wafers, clamps, essentially any surface that may tend to become contaminated in the lithography system.

Optical tweezers have been proposed as devices for removing identified particles, however lasers represent a heat source, which in-scanner is problematic, and even off-line, the lasers themselves can damage the article being cleaned. Not all types of materials may be removed, as there are limitations on size and reflectivity, for example. Optical tweezers furthermore tend to involve large power densities, which again can lead to damage to the object being cleaned.

Thus, an acoustic trapping device using low-power acoustic waves is proposed. By proper manipulation of the acoustic sources, the acoustic radiation forces can trap and manipulate particles without damaging the substrate (or reticle). The range of particle sizes that can be manipulated with acoustic tweezers ranges from nanometer scale up though millimeter scale, rendering acoustic tweezers much more versatile than optical tweezers. Similarly, the range of materials that can be manipulated is likewise greater.

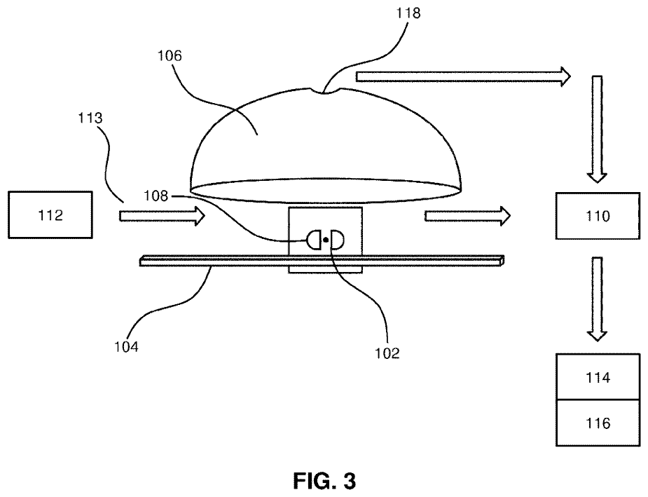

FIG. 3 schematically illustrates an acoustic particle trap in accordance with an embodiment. A particle 102 is detected on a surface of a reticle 104 or other substrate. A hemispherical array of ultrasonic transducers 106 produces a target 3D acoustic wave field 108, that acts to pick and lift the particle 102 from the surface of the reticle 104. The resulting system is contactless, doesn't tend to introduce further contamination, does not damage the substrate being cleaned, and operates at relatively low power density.

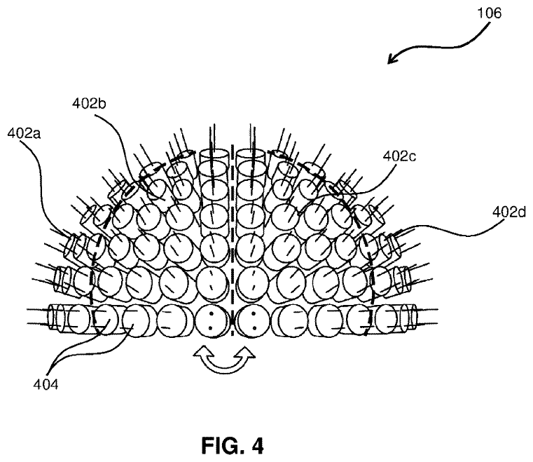

In an embodiment, shown in FIG. 4, the hemispherical array of ultrasonic transducers 106 is arranged into eight individual blocks 402 a, b, c, d of transducers (four of the blocks being on the side not visible in this view). Each block includes one or more ultrasonic transducers 404, and the blocks together comprise the hemispherical array of ultrasonic transducers 106. Adjacent blocks are controlled to be opposite in phase to one another. The use of blocks allows for simplified control, while maintaining sufficient control over the acoustic field. Each block's phase and amplitude is controlled in accordance with an inverse filter W, where

$$W = [ {w}_{0} , {w}_{1} , {w}_{2} … , {w}_{t} ] \qquad ( 1 )$$

The coefficients of the inverse filter are optimized in order to produce a target wave field H, where H=GW, and G is a matrix

$$H = [ {h}_{0} , {h}_{1} , {h}_{2} … , {h}_{c} ] , \qquad ( 2 )$$

$${g}_{ij} = {\sum }_{n = 1}^{m} {M}_{i}^{n} , \qquad ( 3 )$$

$${M}_{i}^{n} = {p}_{0} {J}_{0} ( kr sin {θ}_{i}^{n} ) \frac{1}{{d}_{i}^{n}} exp ( {ikd}_{i}^{n} ) . \qquad ( 4 )$$

The blocks are driven in accordance with the inverse filter to generate an acoustic particle trap 102 at a distance from the transducers as shown in FIG. 3. The entire hemispherical array of ultrasonic transducers 106 can then be scanned across the surface of the object being cleaned in a scanning pattern such that different portions of the surface pass through the acoustic particle trap formed by the acoustic wave field 108, and as the acoustic particle trap passes over a particle, it will lift it and remove it from the surface. Thus, there is not a required inspection step prior to removal of the particle. In principle, the hemispherical array of ultrasonic transducers 106 may be included within a lithography system, for example within the reticle inspection module of the system. This can allow for cleaning without taking the system off-line or removing the reticle to be inspected.

The blocks create a series of trapping nodes, and particles that are passed over by the transducers will levitate to a stable trapping node. In principle, the nodes can then be moved to different positions relative to the transducers for specific desired motion of the particle that is trapped. For example, by increasing the amplitude of the acoustic vibrations, the particle may be shifted upward in the z-dimension.

In an embodiment, an optional system for removing the particles from the chamber once lifted can be included. In this approach, a vacuum system 110 can be used to pull the particles out of the chamber. Alternately or in addition, a gas source 112 can be used to provide a stream of gas through a gas inlet 113. The gas flows through along the surface to be cleaned and carries particles away, for example to a particle reservoir 114. As will be appreciated, for EUV applications, introducing a gas into the system is not preferred, as the optical path is kept under vacuum conditions. Once collected, particles can be measured and statistics may be generated including average size, size standard deviation, and type of material. For this purpose, the reservoir or a downstream component may include a particle detector 116 that is configured to make the necessary measurements.

In an embodiment, the hemispherical array of ultrasonic transducers 106 includes an outlet 118 that is in fluid communication with the particle reservoir 114, which may be via the vacuum system 110 for example, or directly communicated (not shown).

Embodiments may include computer readable medium programmed with instructions, which when executed, perform any of the methods described herein. Furthermore, aspects of the present application may take the form of a computer program product embodied in any one or more physical computer readable medium(s) having computer usable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, device, or any suitable combination of the foregoing. More specific examples (a non-exhaustive list) of the computer readable medium would include the following: an electrical connection having one or more wires, a portable computer diskette, a hard disk, a random access memory (RAM), a read-only memory (ROM), an erasable programmable read-only memory (e.g. EPROM or Flash memory), an optical fiber, a portable compact disc read-only memory CDROM, an optical storage device, a magnetic storage device, or any suitable combination of the foregoing. In the context of this document, a computer readable storage medium may be any tangible medium that can contain or store a program for use by or in connection with an instruction execution system, apparatus, or device.

The computer program instructions may also be loaded onto a computer, other programmable data processing apparatus, or other devices to cause a series of operational steps to be performed on the computer, other programmable apparatus, or other devices to produce a computer implemented process such that the instructions which execute on the computer or other programmable apparatus provide processes for implementing the functions/acts specified in the flowchart and/or block diagram block or blocks.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modems and Ethernet cards are just a few of the currently available types of network adapters.

The description of the present application has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

Aspects of the present disclosure can further be described using the following clauses:
1. A system for removing particles from a surface, comprising:
   a plurality of ultrasonic transducers, arranged in an array;
   a control system, in communication with the plurality of ultrasonic transducers, the control system configured to control phase and amplitude of transducers in the array to generate an acoustic particle trap at a selected location on the surface, and to move a particle trapped in the acoustic particle trap away from the surface; and
   an actuator configured to move the array of ultrasonic transducers in a scanning pattern over the surface such that different portions of the surface pass through the acoustic particle trap.
2. A system as in clause 1, wherein the array is a hemispherical array.
3. A system as in clause 1, wherein the plurality of ultrasonic transducers are arranged in a plurality of blocks, each block including a plurality of the ultrasonic transducers, and wherein the plurality of blocks together comprise the array.
4. A system as in clause 3, wherein a phase and amplitude of ultrasonic transducers in the plurality of ultrasonic transducers comprising each block is controlled as a group, and the control system is configured to control the plurality of blocks to generate the acoustic particle trap and to move the particle trapped in the acoustic particle trap away from the surface.
5. A system as in clause 1, wherein the system is located in a reticle inspection module of a photolithographic apparatus.
6. A system as in clause 1, wherein the array of ultrasonic transducers includes an outlet, the outlet in fluid communication with a particle reservoir for collecting particles removed from the surface.
7. A system as in clause 6, wherein the particle reservoir includes a particle detector configured to measure sizes of collected particles.
8. A system as in clause 1, further comprising:
   a gas source; and
   a gas inlet, configured to receive gas from the gas source, and to generate a flow of gas across the surface, such that particles removed from the surface are entrained in the flow of gas.
9. A method of removing particles from a surface, comprising:
   passing an array of ultrasonic transducers over the surface;
   during the passing, controlling a phase and amplitude of ultrasonic signals produced by ultrasonic transducers in the array such that an acoustic particle trap is generated at a location on the surface; and
   trapping at least one particle in the acoustic particle trap, and controlling a phase and amplitude of ultrasonic signals produced by the ultrasonic transducers in the array to move the trapped at least one particle away from the surface.
10. A method as in clause 9, wherein the array is a hemispherical array.
11. A method as in clause 9, wherein the plurality of ultrasonic transducers are arranged in a plurality of blocks, each block including a plurality of the ultrasonic transducers, and the plurality of blocks together comprising the array.
12. A method as in clause 11, wherein controlling the phase and amplitude of ultrasonic transducers in the plurality of ultrasonic transducers comprises controlling each block as a group, and the plurality of blocks are controlled to generate the acoustic particle trap and to move the particle trapped in the acoustic particle trap away from the surface.
13. A method as in clause 9, wherein the system is located in a reticle inspection module of a photolithographic apparatus.
14. A method as in clause 8, further comprising collecting particles removed from the surface.
15. A method as in clause 14, further comprising, measuring sizes of the collected particles.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid crystal display panels, thin film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g. a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1. A system for removing particles from a surface, the system comprising:
a plurality of ultrasonic transducers, arranged in an array;
a control system, in communication with the plurality of ultrasonic transducers, the control system configured to control phase and amplitude of transducers in the array to generate an acoustic particle trap at a selected location on the surface, and to move a particle trapped in the acoustic particle trap away from the surface; and
an actuator configured to provide relative movement between the array of ultrasonic transducers and the surface in a scanning pattern such that different portions of the surface pass through the acoustic particle trap.

2. The system as in claim 1, wherein the array is a hemispherical array.

3. The system as in claim 1, wherein the plurality of ultrasonic transducers are arranged in a plurality of blocks, each block including a plurality of the ultrasonic transducers, and wherein the plurality of blocks together comprise the array.

4. The system as in claim 3, wherein a phase and amplitude of ultrasonic transducers in the plurality of ultrasonic transducers comprising each block is controlled as a group, and the control system is configured to control the plurality of blocks to generate the acoustic particle trap and to move the particle trapped in the acoustic particle trap away from the surface.

5. The system as in claim 1, located in a reticle inspection module of a photolithographic apparatus.

6. The system as in claim 1, wherein the array of ultrasonic transducers includes an outlet, the outlet in fluid communication with a particle reservoir for collecting particles removed from the surface.

7. The system as in claim 6, wherein the particle reservoir includes a particle detector configured to measure sizes of collected particles.

8. The system as in claim 1, further comprising:
a gas source; and
a gas inlet configured to receive gas from the gas source, and to generate a flow of gas across the surface, such that particles removed from the surface are entrained in the flow of gas.

9. A method of removing particles from a surface, the method comprising:
providing relative movement between an array of ultrasonic transducers and the surface;
during the relative movement, controlling a phase and amplitude of ultrasonic signals produced by ultrasonic transducers in the array such that an acoustic particle trap is generated at a location on the surface; and
trapping at least one particle in the acoustic particle trap, and controlling a phase and amplitude of ultrasonic signals produced by the ultrasonic transducers in the array to move the trapped at least one particle away from the surface.

10. The method as in claim 9, wherein the array is a hemispherical array.

11. The method as in claim 9, wherein the plurality of ultrasonic transducers are arranged in a plurality of blocks, each block including a plurality of the ultrasonic transducers, and the plurality of blocks together comprising the array.

12. The method as in claim 11, wherein controlling the phase and amplitude of ultrasonic transducers in the plurality of ultrasonic transducers comprises controlling each block as a group, and the plurality of blocks are controlled to generate the acoustic particle trap and to move the particle trapped in the acoustic particle trap away from the surface.

13. The method as in claim 9, wherein the array of ultrasonic transducers is located in a reticle inspection module of a photolithographic apparatus.

14. The method as in claim 9, further comprising collecting particles removed from the surface.

15. The method as in claim 14, further comprising measuring sizes of the collected particles.

16. A non-transitory machine readable medium including instructions therein, the instructions, when executed by an apparatus, configured to cause the apparatus to at least:
during a relative movement between an array of ultrasonic transducers and a surface, control a phase and amplitude of ultrasonic signals produced by ultrasonic transducers in the array such that an acoustic particle trap is generated at a location on the surface; and
control a phase and amplitude of ultrasonic signals produced by the ultrasonic transducers in the array to move a trapped at least one particle in the acoustic particle trap away from the surface.

17. The medium of claim 16, wherein the array is a hemispherical array.

18. The medium of claim 16, wherein the array of ultrasonic transducers is located in a reticle inspection module of a photolithographic apparatus.

19. The medium of claim 16, wherein the array of ultrasonic transducers includes an outlet, the outlet in fluid communication with a particle reservoir for collecting particles removed from the surface.

20. The medium of claim 16, wherein the instructions are further configured to cause the apparatus to generate a flow of gas across the surface, such that particles removed from the surface are entrained in the flow of gas.
